(19) United States
(12) Patent Application Publication
(10) Pub. No.: US 2026/0118389 A1
(43) Pub. Date: Apr. 30, 2026

(54) Configuration Method for a Monitoring Device for Improved Quality Forecasting of Workpieces

(71) Applicant: Siemens Aktiengesellschaft, Muenchen (DE)

(72) Inventor: Alexandr SADOVOY, Berlin (DE)

(21) Appl. No.: 19/151,714

(22) PCT Filed: Jan. 17, 2024
(86) PCT No.: PCT/EP2024/051015

§ 371 Date: Jul. 29, 2025

(30) Foreign Application Priority Data
Jan. 30, 2023 (EP) 23153923.0

(51) Int. Cl. G01R 19/00; G06N 20/00

(52) U.S. Cl. CPC G01R 19/0092; G06N 20/00

(57) ABSTRACT

A computer program product, a monitoring method for a production process in a production system, a production system provided with a monitoring device and a method for configuring the monitoring device, which is configured to monitor the production process in the production system for quality forecasting, wherein a process variable is detected and, based on this, a plurality of aggregation variables are determined, where a quality parameter is also detected, multiple aggregation variables and the quality parameter are combined to form a workpiece data set, a respective interdependence between a respective aggregation variable and the quality parameter is additionally determined and a forecasting variable is determined from among the aggregation variables based on the determined interdependence, the forecasting variable is specified as the variable of the production process to be monitored for the operation of the monitoring device.

### CROSS-REFERENCE TO RELATED APPLICATIONS

This is a U.S. national stage of application No. PCT/EP2024/051015 filed 17 Jan. 2024. Priority is claimed on European Application No. 23153923 filed 30 Jan. 2023, the content of which is incorporated herein by reference in its entirety.

### BACKGROUND OF THE INVENTION

### 1. Field of the Invention

The invention relates to a method for configuring a monitoring device belonging to a production system, a monitoring method for a production process, a computer program product for at least partly performing the method for forecasting the quality results, a correspondingly configured monitoring device and to a production system provided with such a monitoring device.

### 2.

International Application WO 2022/063702 A1 discloses a method for quality control of a series-produced product, in which method parameters of the production process are recorded. The product is thereupon subjected to an inspection and a quality assessment is conducted on the basis thereof. The recorded parameters and the quality assessment are supplied to a machine learning model. A quality prediction is performed based on the recorded parameters and analyzed for concurrence with or deviation from the quality assessment. In this way, a machine learning process is performed via which the machine learning model is trained to detect causes of quality problems.

Production systems are furnished with an increasing number of sensors, with the result that an increasing volume of data is available to be taken into consideration for the monitoring of said systems. This makes an appropriate configuration of a monitoring device for such production systems more complex and more cost-and labor-intensive. There is also a requirement for flexible production systems that can be quickly retooled to cater for other production processes and reliably provide high product quality following a short ramp-up time. There is a need for a way to configure monitoring devices of production systems rapidly and as far as possible automatically.

### SUMMARY OF THE INVENTION

In view of the foregoing, it is therefore an object of the invention to provide a method for configuring a monitoring device belonging to a production system, a monitoring method for a production process, a computer program product for at least partly performing the method for forecasting the quality results, a correspondingly configured monitoring device and to provide a production system provided with such a monitoring device

These and other objects and advantages are achieved in accordance with the invention by a method for configuring a monitoring device belonging to the production system. The monitoring device is configured to monitor a production process that is performed via the production system. The production process may be a cyclical production process in which workpieces are processed repeatedly in the same way. The workpiece may be a blank, a machined blank or a component requiring repair. The method is based on the premise that the monitoring device is disposed in a basic state in which the device is at least suitable for receiving inputs via which a process variable that is to be monitored as a forecasting variable can be specified. In the basic state, the monitoring device may furthermore be free from known or suspected relationships that have an effect on an intended quality of the workpiece, i.e., free from a corresponding configuration.

The method comprises a first step in which at least one predefinable process variable is measured at a component of the production system. The predefinable process variable is measured during a pass of the production process on a workpiece. The process variable can be a quantity that is measurable at the respective component, for example, an electric current intensity of the heating elements or a temperature in the furnace during a curing process. The at least one process variable is a time-variable quantity such that the process variable measured in the first step is formed as a time series, i.e., as a plurality of data points that can be sorted with respect to time, for example, based on a timestamp. The process variable is stored at least partially and at least temporarily in the first step and is thus provided for further steps. The process variable can be specified by a user or via a table and/or an algorithm, for example, an expert knowledge database.

The method further comprises a second step in which a predefinable quality parameter of the workpiece is acquired. The quality parameter can be a physical quantity that is directly present at the workpiece and can be measured. For example, a material property of the workpiece or a deviation of a material property from a nominal value can be a quality parameter. Such a material property may be, inter alia, a hardness or porosity of the workpiece. An intended property of the workpiece is quantifiable via the quality parameter. the quality parameter may be specified by a user or via a table and/or an algorithm, for example, an expert knowledge database.

The method additionally comprises a third step in which aggregation variables are determined based on the at least one process variable from the first step. The aggregation variables in each case represent a quantity derived from the process variable formed as a time series. In particular, the aggregation variables can be statistical quantities of the at least one process variable. At least one aggregation variable can have a data volume that is smaller than the data volume of the underlying process variable. The third step can be performed after the first step or at least in part concurrently with the first step.

The method further comprises a fourth step in which the aggregation variables are combined with the quality parameter that is acquired in the second step and as a result a workpiece data set is formed. In the process, the aggregation variables are combined with the quality parameter that belongs to the same workpiece. As a result, the workpiece data set comprises, on a workpiece-specific basis, a plurality of aggregation variables in which a relationship with the associated quality parameter is conceivable. Furthermore, the workpiece data set can be free of the process variable on the basis of which the aggregation variables stored therein are determined. The fourth step can be performed after the third step or at least in part concurrently with the third step. Further, the first to fourth steps are performed multiple times in the method in accordance with the invention, and in this way a plurality of workpiece data sets are provided, for example, for a plurality of different workpieces. The plurality of workpiece data sets are provided for a following fifth step.

In the fifth step of the method in accordance with the invention, a respective interdependence between a plurality of the aggregation variables and the quality parameter is determined. One of the aggregation variables is identified as a forecasting variable based on a determined interdependence. The respective interdependencies can be detected via a machine learning model. Consequently, in the fifth step, it is detected between which individual aggregation variable or a plurality of aggregation variables and the quality parameter there exists a meaningful relationship. This relationship is characterized by the at least one detected interdependence and quantified as measurable. The fifth step can be performed via a machine learning model, for example, using a decision tree, random forest, gradient boost, XGBoost or neural network.

The method further comprises a sixth step in which the forecasting variable detected in the fifth step is specified to the monitoring device as the quantity of the production process that is to be monitored. For this purpose, a designation of the forecasting variable can be transmitted to the monitoring device, for example. The configuration of the monitoring device is set at least in part as a result of the forecasting variable being specified.

In the method in accordance with the invention, a plurality of aggregation variables are derived from the process variable embodied as a time series. Time series are extensive in terms of data volume, such that the processing to form aggregation variables represents a data compression. As a result, the aggregation variables can be determined substantially concurrently in step with the production process. The workpiece data set produced in the method in accordance with the invention is small in terms of data volume, thus significantly reducing the number of dimensions and the complexity of the machine learning model. Even given an increased number of workpiece data sets, their evaluation in the fifth step, i.e., the determining of interdependencies, the underlying data volume still remains relatively small, which in turn permits the interdependencies to be determined in an accelerated manner. The invention is based among other things on the surprising recognition that aggregation variables are at least sufficiently informative as forecasting variables for a quality parameter. Identifying an aggregation variable as a forecasting variable requires no specification of known or suspected relationships within the production process and as a result can be performed automatically. The method is suitable for rapidly generating and specifying meaningful forecasting variables in a production system, thereby enabling a prediction of quality results on processed workpieces.

In an embodiment of the inventive method, data points belonging to a nonproductive time action of the corresponding component are determined based on the timestamp or based on the value of the predefinable process variable, i.e., of timestamps or values of individual data points of the process variable. By a nonproductive time action is to be understood as any actuation of the component in which no productive activity of the corresponding production process is present, such as during a nonproductive time movement of a machine tool in a different process phase or an idling cycle. Such data points belonging to a nonproductive time action are removed.

As a result, the process variable on the basis of which the aggregation variables are determined contains only data points that characterize the corresponding production process. The generation of misleading aggregation variables is reduced or prevented in this way. Alternatively or in addition, the at least one process variable used in the third step can be checked via a further process variable and in this way data points belonging to a nonproductive time action can be detected. The data points detected in this way are also removed. Aggregation variables possessing increased relevance can be generated via a filtering of this type.

In a further embodiment of the inventive method, the fifth step, i.e., the determining of the interdependencies, is performed via a machine learning model. Such a machine learning model can be formed, for example, as a decision tree, random forest, gradient boost, XGBoost or neural network. A multiplicity of machine learning models are suitable for quickly and reliably determining interdependencies in data sets, such as the tool data sets. The machine learning model employed in the fifth step is consequently separately replaceable. As a result, the disclosed embodiments of the method are easily suitable for deploying future machine learning models also and for exploiting their technical potential.

The machine learning model can furthermore be trained based on a plurality of workpiece data sets that are provided in accordance with the first, second, third and fourth step. Such workpiece data sets can be obtained, for example, via a configuration method on a different production system or from previous iterations of the disclosed embodiments of the method. The inventive method is consequently suitable for generating workpiece data sets concurrently with the operation of the production system, i.e., with the production process, which workpiece data sets are suitable for a further training of the machine learning model. Such further workpiece data sets are each generated in relation to further workpieces. A further training of this type can be conducted on a hardware platform that is separate from the production system. The machine learning model is therefore updated during the production process via a further-trained version. The performance of the disclosed embodiments of the method can accordingly be increased automatically.

In the disclosed embodiments of the method, one of the aggregation variables can furthermore be identified as a forecasting variable if a quantifiable relationship between the corresponding aggregation variable and the quality parameter, for example, a linear or nonlinear interdependence, is present which is characterized by an interdependence coefficient if the interdependence coefficient of the corresponding interdependence exceeds a predefinable threshold value in terms of amount. With the predefinable threshold value, it is possible to set the present quantifiable relationship to a strength below which the latter is ignored in the inventive method. By way of the threshold value, it is therefore possible to specify how many aggregation variables are to be expected as forecasting variables. The fewer forecasting variables are specified in turn for the monitoring device in the sixth step, the more efficiently the production process can be monitored. The impact of a forecasting variable on the quality parameter is also quantifiable by means of the threshold value.

Further, at least one of the aggregation variables may be formed as a maximum, minimum, arithmetic mean, geometric mean, or as a standard deviation of the associated process variables. These represent quantities that can easily be determined from a time series and can be stored economically in terms of data volume, thereby providing an increased compression compared to the underlying process variable. For statistical functions of this type, there are efficient algorithms available, for example, in repositories known as function libraries, which permit a rapid determination of the respective aggregation variable. Alternatively or in addition, the aggregation variable can also be any other statistical quantity which is derived from the process variable.

In a further embodiment of the method, at least one of the aggregation variables can be formed as a coefficient set of a comparison function, for example, of a fitting function. The coefficient set can comprise one or more coefficients. The comparison function may, for example, be a function via which a variation with respect to time of at least one process variable is approximated at least in sections. The comparison function, and hence also the associated coefficient set, can be determined via an evaluation unit that is assigned to a component that is configured to have an effect indirectly or directly on workpieces. Alternatively or in addition, the comparison function, and hence its coefficient set, can be determined via the monitoring device. A complex variation with respect to time of the process variables is also reproducible economically in terms of data via the coefficient set of the comparison function. Accordingly, complex relationships can also be taken into account with reduced storage and computing requirements when determining the at least one forecasting variable. Particularly significant forecasting variables can be determined as a result. Alternatively or in addition, at least one of the aggregation variables can be configured as a comparison value in relation to a model output value of a process model or a subprocess model. The process model or subprocess model can be formed as a physical model of the production process or subproduction process. A linear or exponential model comprising corresponding coefficient sets can be used as an example to map the course of the process variables in the corresponding process phase during the production of the workpieces. Process models or subprocess models represent realistic mappings of the underlying production process which can also be used via the inventive method. Further, alternatively or in addition, the at least one aggregation variable can be formed as a process interruption specification that is determined based on the process variable measured in the first step. The process interruption specification can indicate a duration of an interruption or a number of interruptions of the production process, a start and end time of the interruption and/or a frequency indicator of interruptions. A process interruption specification is suitable for indicating the likelihood and severity of a deterioration in product quality. For example, a temporary failure of a heating element in a hardening furnace can have repercussions of different severity on the curing process depending on the position in the traversed temperature profile. All in all, by having recourse to data of different types, i.e. process variables, the inventive method is suitable for determining aggregation variables. In this way, it is possible to recognize relationships in the production process in the form of forecasting variables that are not perceptible to a user. The monitoring device can therefore be set to a forecasting variable that possesses an increased significance with respect to a quality parameter.

Furthermore, the first to sixth step can be performed repeatedly in step with the production process. In this way, there are obtained, from a plurality of workpieces, workpiece data sets on the basis of which the machine learning model used in the fifth step can be trained further. The overall performance of the monitoring device is increased further as a result.

The objects and advantages are also achieved in accordance with the invention by a quality prediction method for a production process that is performed via a production system. The production system comprises at least one component via which the production process is performed, for example, a heat treatment furnace for the curing process. The quality prediction method comprises a first step in which the production system is provided in an active operating state in which the production process that is to be monitored runs. In particular, a workpiece can be processed in this case. At least one process variable is also measured in the first step. The quality prediction method further comprises a second step in which, based on the measured process variable, at least one forecasting variable is determined that may be formed as an aggregation variable derived from the process variable. The inventive quality prediction method also includes a third step in which a prediction value for a quality parameter of a workpiece is determined based on the at least one forecasting variable. Here, the parameter is an expected quality parameter. In the third step, the determined prediction value is compared with an associated predefinable setpoint or with at least one predefinable tolerance limit, i.e., it quantifies a difference between these. The quality prediction method further comprises a fourth step in which a warning is output to a user and/or to a data interface if a condition of the production system at variance with its normal state is detected based on the comparison in the third step. In accordance with the invention, the at least one forecasting variable determined in the second step is specified via a method for configuring the monitoring device in accordance with one of the above-described embodiments. Such a quality prediction method provides a targeted and reliable detection of a decline in the quality of the workpieces that are being processed in the monitored production process.

In an embodiment of the quality prediction method, its third step is performed while its first step is being performed. Accordingly, a process variable is measured during a processing of the workpiece and the prediction value is determined based on a subset of the data points associated with the corresponding production process, for example, since the start of the processing of the workpiece. Thus, even before termination of the underlying processing of the workpiece, the inventive quality prediction method determines the prediction value for the quality parameter, which is compared with the associated predefinable setpoint or the predefinable tolerance limit. Particularly during long processing phases, for example, a curing process in the hardening furnace, this permits a timely quality prediction and accordingly a prompt response to imminent losses in quality.

Alternatively, at least the third step of the quality prediction method can be performed when the first step has been completed. As a result, all the data points generated during the processing of the corresponding workpiece are used for determining the prediction value. Inapplicable prediction values are avoided in this way. This applies in particular to forecasting variables, i.e., to an aggregation variable generated solely due to the dynamics of the underlying process variable. This may be, for example, an arithmetic mean of a temperature profile that is still at ambient temperature at the start of the first step.

Whether the third step is performed during the first step or after the first step can be specified by a user, for example.

The objects and advantages are also achieved in accordance with the invention by a computer program product that is configured to receive at least one process variable and to process the process variable. A forecasting variable can be determined as a result of the processing of the process variable. In accordance with the invention, the computer program product is configured to perform a method for configuring a monitoring device in accordance with one of the above-disclosed embodiments. The computer program product can be configured to be executed on a control unit belonging to the production system upon which the process variable that can be received and processed by the computer program product is measured. Further, the computer program product can be designed as monolithic, i.e., as executable on a single hardware platform, for example, on a programmable logic controller (PLC), a master computer and/or an operator station that is coupled to the production system or belongs to the production system. Alternatively, the computer program product can be constructed in a modular configuration and can comprise a plurality of subroutines that can be executed on separate hardware platforms and that interact via data interchange in order to realize the functionality of the inventive method. For example, the computer program product can be executable in the form of subroutines on different computers of a computer cloud. The computer program product can be formed in particular as software for an edge device or a computer cloud. Further, the computer program product can be formed at least in part as hardwired, for example as a chip, integrated circuit or FPGA. Alternatively or in addition, the computer program product can be formed at least in part as software.

The objects and advantages are further achieved in accordance with the invention by a monitoring device that is configured to monitor a production process that is performed via a production system. The monitoring device is suitable for receiving at least one process variable and, based on the process variable, for determining at least one forecasting variable. In accordance with the invention, the forecasting variable is designed via a method for configuring a monitoring device in accordance with to one of the above-disclosed embodiments. Alternatively or in addition, the monitoring device is configured to perform a monitoring method in accordance with one of the above-disclosed embodiments. Such a monitoring device permits the associated production system to be set up quickly and ensures a reliable quality prediction of the workpieces processed therewith.

Similarly, the objects and advantages are achieved in accordance with the invention by a production system that comprises a plurality of components, each of which is configured for processing a workpiece, in particular in the course of a production process. The production system also comprises a monitoring device that is connected to the components. In accordance with the invention, the monitoring device is in accordance with one of the above-disclosed embodiments. Production systems of the aforesaid type provide a reliable prediction for the quality of the workpieces processed therewith.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The invention is explained in more detail below with reference to individual embodiments illustrated in figures. The figures should be read as mutually complementary to the extent that like reference signs in different figures have the same technical meaning. The features of the individual embodiments can also be combined with one another. Furthermore, the embodiments shown in the figures can be combined with the above-outlined features, in which:

FIG. 1 schematically shows a first embodiment of the inventive configuration method in a first stage;

FIG. 2 schematically shows a second embodiment of the inventive configuration method during its first or second step;

FIG. 3 schematically shows the first embodiment of the inventive configuration method in a second stage;

FIG. 4 schematically shows the first embodiment of the inventive configuration method in a third stage;

FIG. 5 schematically shows a first embodiment of the inventive monitoring method.

### DETAILED DESCRIPTION OF THE EXEMPLARY EMBODIMENTS

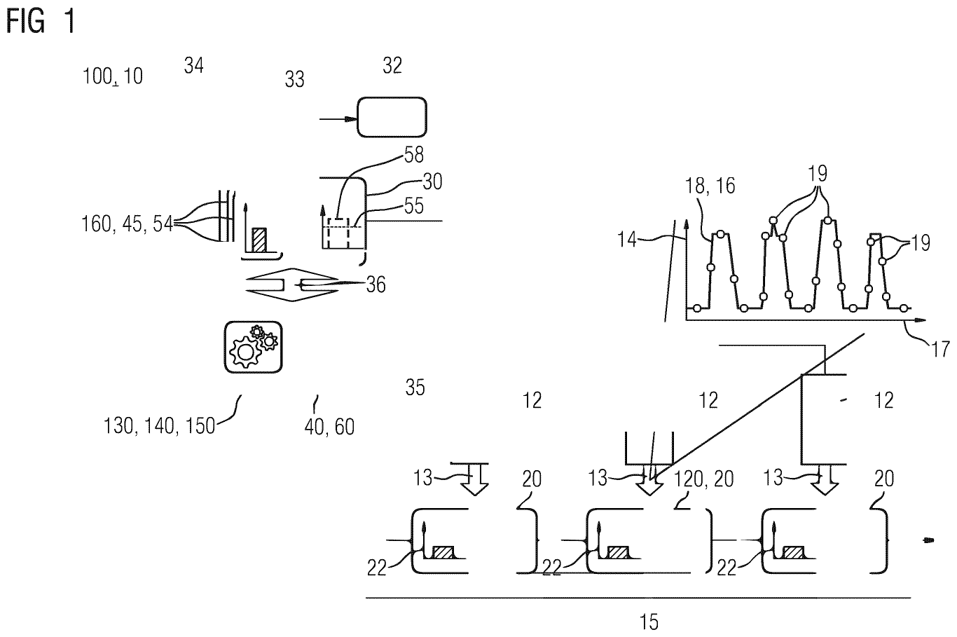

FIG. 1 shows a first embodiment of the inventive method 100 for configuring a monitoring device 30 in a first stage. The monitoring device 30 belongs to a production system 10 upon which a production process 15 can be performed in which workpieces 20 are processed. For this purpose, the production system 10 is provided with a plurality of components 12 that are configured for indirectly or directly processing the workpieces 20. The production process 15 is formed as a cyclical production process such that the components 12 repeatedly perform substantially the same processing 13 per workpiece 20. The workpieces 20 are processed successively station by station. The components 12 can be formed as drive motors for tools, for example. The components 12 of the production system 10 are communicatively connected to the monitoring device 30 and to a control unit 40 of the production system 10 for the purpose of transmitting measurement signals 35. The control unit 40 and the monitoring device 30 are coupled to one another via a communicative data link 36. Further, a process model 42 of the underlying production process 15, which comprises a digital twin 44 of the production system 10, executes on the control unit 40.

A processing 13 of a workpiece 20 performed by a component 12 is characterized by at least one process variable 16 that can be measured in the inventive method 100. The process variable 16 is a measurable quantity that forms a time series 18 during a processing 13 of the respective workpiece 20. A measured process variable 20 comprises a plurality of data points 19 that form the time series 18 along a horizontal time axis 17. Accordingly, a timestamp is present for each of the data points 19. The value of the process variable 20 is represented in FIG. 1 on a vertical value axis 14. As a result of the processing 13 of the workpieces 20, the workpieces 20 undergo a change in a physical variable that is measurable and represents a quality parameter 22. The quality parameter 22 may be, for example, a dimension of the workpiece 20 that is to be machined to a predefined measure.

The method 100 comprises a first step 110 in which a predefinable process variable 16 is measured that is present at one of the components 13, for example, an electric current intensity at a drive motor. The process variable 16 is measured on the component 12 by an acquisition means (not shown in further detail) during a processing 13 of the respective workpiece 20. In the first step 110, the measured process variable 16 can be transmitted in the form of a measurement signal 35 to the control unit 40. After the first step 110, or in part during the first step 110, a second step 120 is performed in the inventive method 100. Therein, a predefinable quality parameter 22 is acquired on the respective workpiece 20 that is processed in the first step 110. The production system 10 is provided with suitable acquisition means (not shown in further detail) for this purpose.

Based on the process variable 16, at least one aggregation variable 45 is to be determined that is to be specified as a forecasting variable 54 for the monitoring device 30, i.e., is to be set in its configuration, via the inventive method 100. To that end, a third, fourth and fifth step 130, 140, 150 are performed via the control unit 40, which steps are described in more detail in relation to the following figures. The at least one forecasting variable 54 determined in the fifth step 150 is specified to the monitoring device 30 in a sixth step 160. Alternatively or in addition, at least one of the steps 130, 140, 150 may also be performed via a different hardware platform than the control unit 40.

Given predefined forecasting variables 54, the monitoring device 30 is suitable for performing a monitoring method 200 in which a prediction value 58 is determined which corresponds to a quality parameter 22 expected for the respective workpiece 20. By synchronizing with a predefinable setpoint 55 it is determined in the monitoring method 200 whether a condition of the production system 10 at variance with its normal state is present. Depending on the result thereof, a warning 33 can be output to a user via a user interface 32, for example, a visual display or an acoustic signal. Alternatively or in addition, the warning 33 can also be output to a data interface 34. The control unit 40 is provided with a computer program product 60 which is configured to perform at least one of the steps 110, 120, 130 shown in FIG. 1.

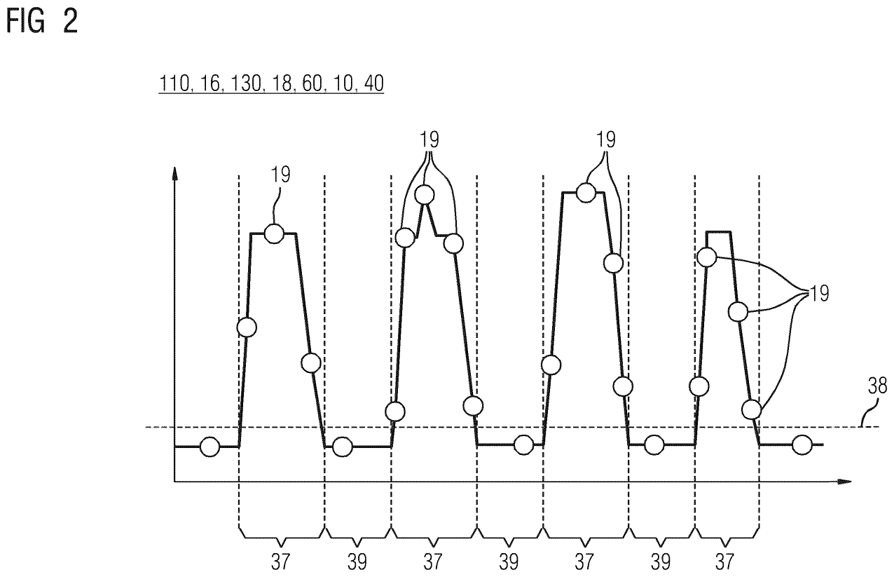

A second embodiment of the inventive method 100 is shown in FIG. 2 during the first or third step 130. A process variable 16 measured in a first step 110, as shown in FIG. 1 for example, is present which is formed as a time series 18. The process variable 16 comprises a plurality of data points 19 that are arranged in order along a horizontal time axis 17. The value of the respective data points 19 is represented in FIG. 2 by a vertical value axis 14. An adjustable threshold value 38 is shown that is derived from a further process variable 16 (not shown). Data points 19 are identified as data points 19 belonging to an active phase 37 of the associated component 12, and consequently of the production process 15. Data points 19 below the threshold value 38 are detected as such data points 19 that belong to a nonproductive time action of the associated component 12, and consequently of the production process. Such nonproductive time actions form inactive phases 39 of the production process 15 or, as the case may be, of the associated component 12 between the active phases 37. For the further processing of the process variable 16, data points 19 belonging to the nonproductive time action are removed and thus ignored in the further method 100. In this way, it is ensured that the processing of data points 19 that belong to an inapplicable process phase and consequently cannot lead to the detection of a forecasting variable 54 is avoided in the inventive method 100. The active phases 37 each correspond to process phases of the production process 15 in which a workpiece 20 is processed. The second embodiment shown in FIG. 2 can be combined with the first embodiment of the method 100, as shown in FIG. 1. The steps shown in FIG. 2 can be performed at least in part via a computer program product 60 (not shown in further detail) which is executable on a control unit 40 of the production system 10.

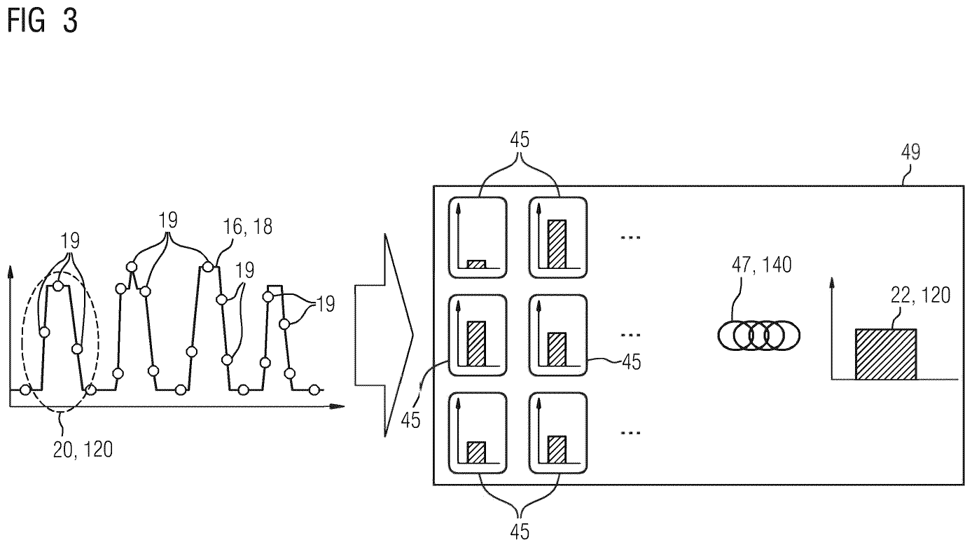

The first embodiment of the inventive method 100 is shown in FIG. 3 schematically in a second stage that follows on from the first stage shown in FIG. 1. A third step 130 of the method 100 is performed in which the process variable 16 measured in the first step 110 is present in the form of a time series 18. A plurality of aggregation variables 45 are determined therein based on the process variable 16. The aggregation variables 45 are determined for data points 19 of a process phase in which a workpiece 20 is processed in a second step 120. The aggregation variables 45 represent a processing of the corresponding process variable 16 and each possess a smaller data volume than the process variable 16 itself. In total, the aggregation variables 45 may also constitute a smaller data volume than the corresponding process variable 16. The aggregation variables 45 may be, for example, a maximum, a minimum, an arithmetic mean, a geometric mean and/or a standard deviation of the process variable 16 that are determined based on their data points 19. In the inventive method 100, the different aggregation variables 45 may be predefined as fixed values or be selected by means of an algorithm or by a user.

In a fourth step 140, the determined aggregation variables 45 are linked, i.e., combined, with the quality parameter 22 acquired in the first step 110, as shown in FIG. 1, for example. By combining 47 the aggregation variables 45 with the quality parameter 22, a workpiece data set 49 is formed. The workpiece data set 49 may likewise possess a smaller data volume than the underlying process variable 16. The workpiece data set 49 generated in the fourth step 140 is provided for a following fifth step 150. The control unit 40 of the production system 10 is provided with a computer program product 60 that is configured to perform at least one of the steps 130, 140 shown in FIG. 3.

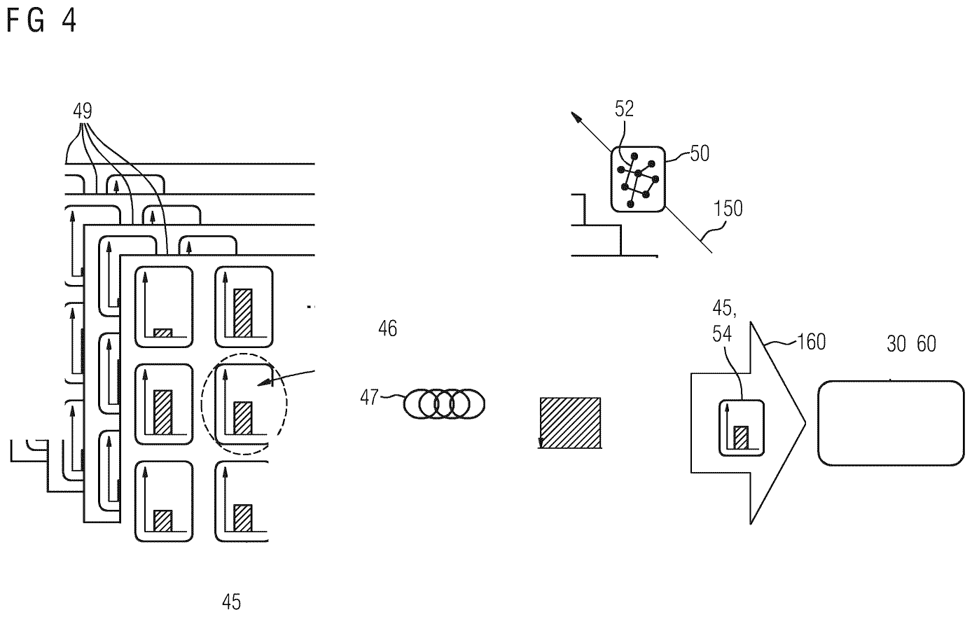

A third stage of the first embodiment of the inventive method 100 is shown schematically in FIG. 4. The third stage follows on from the second stage shown in FIG. 3. The third stage according to FIG. 4 proceeds on the basis that the first, second, third and fourth step 110, 120, 130, 140 have been performed multiple times and that a plurality of workpiece data sets 49 are present. Each of the workpiece data sets 49 comprises a plurality of aggregation variables 45, each of which is linked to a quality parameter 22. The linking, i.e., the combining 47, in the respective workpiece data set 49 occurs in the fourth step 140 of the method 100. The third stage includes a fifth step 150 of the method 100 in which the workpiece data sets 49 are processed by a machine learning model 50, which is formed as a neural network 52, for example. In the fifth step 150, at least one interdependence 46 between the aggregation variables 45 of the processed workpiece data sets 49 and the associated quality parameter 22 is determined by the machine learning model 50. The interdependence 46 can be quantified via an interdependence coefficient (not shown in further detail). Based on the interdependence 46 detected in the fifth step 150, the associated aggregation variable 45 is identified and selected as a forecasting variable 54. The forecasting variable 54 can be selected from among the aggregation variables 45 by, among other things, the degree of interdependence 46, i.e., the associated interdependence coefficient. The selection of the aggregation variable 45 as a forecasting variable 54 can also be performed via the machine learning model 50.

In a sixth step 160, the detected forecasting variable 54 is transmitted to the monitoring device 30 and thus specified as quantities to be monitored for an operation of the production system 10. The monitoring device 30 is configured accordingly via the inventive method 100. The fifth and/or sixth step 150, 160 are/is performed in the inventive method 100 by the control unit 40. The control unit 40 is equipped with a computer program product 60 that is configured to perform at least one of the steps 150, 160 shown in FIG. 4. Alternatively or in addition, at least one of the steps 150, 160 can also be performed by a different hardware platform than the control unit 40.

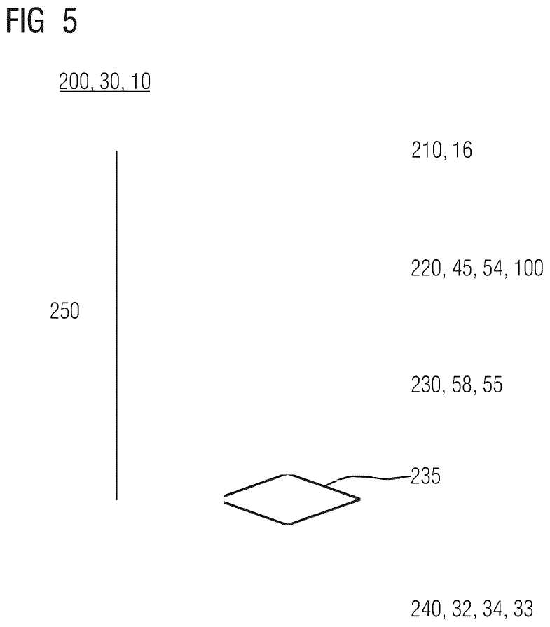

A first embodiment of the inventive monitoring method 200 is shown schematically in FIG. 5. The monitoring method 200 is performed via a monitoring device 30 of a production system 10 which is at least partly configured via an inventive method 100. The monitoring method 200 comprises a first step 210 in which the production system 10 is provided in an active operating state and at least one process variable 16 is measured. During the active operating state, at least one workpiece 20 is processed by the production system 10. There follows a second step 220 in which the process variable 16 is processed further and thus an aggregation variable 45 is determined. The aggregation variable 45 is specified as a forecasting variable 54 via the configuration of the monitoring device 30 and is thus defined, i.e., set, as a quantity that is to be monitored. The forecasting variable 54 is specified via the inventive method 100 for configuring the monitoring device 30. There follows a third step 230 in which a prediction value 58 is determined based on the determined forecasting variable 54. The prediction value 58 represents a quality parameter 22 that is to be expected for the corresponding workpiece 20 that is processed in the active operating state during the first step 210. The prediction value 58 is compared with a predefinable setpoint 58. Based on the comparison thus performed, a branch 235 results in the monitoring method 200. If it is established that the prediction value 58 satisfies the requirements defined by the setpoint 55, then a condition of the production system 10 at variance with its normal state is detected. Accordingly, a return 250 is made to the first step 210 of the monitoring method 200. If a condition of the production system 10 at variance with its normal state is detected as a result of the comparison between the setpoint 55 and the prediction value 58, then a fourth step 240 follows. In the fourth step 240, a warning 33 is output via a user interface 32 and/or a data interface 34. The monitoring method 200 thereupon reaches an end state 300.

Thus, while there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements and/or method steps that perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-13. (canceled)

14. A method for configuring a monitoring device which is configured to monitor a production process in a production system and which is present in a basic state, the method comprising:
a) measuring at least one predefinable process variable at a component of the production system, the process variable being formed as a time series;
b) measuring a predefinable quality parameter of a workpiece which has been processed by the production system;
c) determining aggregation variables based on the process variable from step a);
d) combining a plurality of aggregation variables and the quality parameter in a workpiece data set, a plurality of workpiece data sets being provided in accordance with steps a) to d) for a plurality of different workpieces; and
e) determining a respective interdependence between a respective aggregation variable and the quality parameter and identifying a forecasting variable from among the aggregation variables based on the determined interdependencies; and
f) specifying the forecasting variable for operation of the monitoring device as the quantity to be monitored of the production process;
wherein at least one of the aggregation variables is formed as a coefficient set of a fitting function, via which a variation with respect to time of at least one process variable is approximated in sections;
wherein a nonlinear interdependence is present between corresponding aggregation variables and the quality parameter; and
wherein an interdependence coefficient and the production process is a cyclical production process in which workpieces are repeatedly processed in the same way.

15. The method as claimed in claim 14, wherein during step a) data points belonging to a nonproductive time action of the component of the production system are determined and removed based on at least one of (i) a timestamp of the predefinable process variable and (ii) a further predefinable process variable.

16. The method as claimed in claim 14, wherein step e) is performed via a machine learning algorithm.

17. The method as claimed in claim 15, wherein step e) is performed via a machine learning algorithm.

18. The method as claimed in claim 16, wherein the machine learning algorithm is trained based on a plurality of workpiece data sets which are provided in accordance with steps a) to d).

19. The method as claimed in claim 14, wherein one of the aggregation variables is identified as a forecasting variable if an interdependence having an interdependence coefficient which exceeds a predefinable threshold value in terms of amount is present between the corresponding aggregation variables and the quality parameter.

20. The method as claimed in claim 14, wherein at least one of the aggregation variables is formed as one of a maximum, minimum, arithmetic mean, geometric mean and standard deviation of the associated process variable.

21. The method as claimed in claim 14, wherein at least one further variable of the aggregation variables is formed as one of (i) a comparison value in relation to a model output value of a process model or subprocess model, (ii) a derivative of predefinable order of the process variable and (iii) a process interruption specification which is determined based on the process variable.

22. The method as claimed in claim 14, wherein steps a) to f) are performed repeatedly concurrently in step with the production process.

23. A quality prediction method for a production process which is performed via a production system comprising at least one component, the method comprising:
a) providing the production system in an active operating state and measuring at least one process variable;
b) determining at least one forecasting variable based on the measured at least one process variable;
c) determining a prediction value based on the forecasting variable for a quality parameter of a workpiece and comparing the prediction value with an associated predefinable setpoint or a predefinable tolerance limit;
d) outputting a warning to at least one of a user and a data interface if a condition of the production system at variance with a normal state of the production system is detected based on the comparison in step c);
wherein the forecasting variable is specified via the method as claimed in claim 1.

24. The quality prediction method as claimed in claim 22, wherein at least step c) is performed while step a) is being performed or wherein at least step c) is performed when step a) has been completed.

25. A non-transitory computer program product for receiving at least one process variable and processing the at least one process variable to determine at least one forecasting variable which is executable on a control unit of a production system, at which the process variable which is processed and received by the computer program product is measured, wherein the computer program product is configured to perform the method as claimed in claim 14.

26. A monitoring device for monitoring a production process on a production system which is configured to receive at least one process variable and to determine at least one forecasting variable based on the process variable, wherein the at least one forecasting variable is specified by:
a) measuring at least one predefinable process variable at a component of the production system, the process variable being formed as a time series;
b) measuring a predefinable quality parameter of a workpiece which has been processed by the production system;
c) determining aggregation variables based on the process variable from step a);
d) combining a plurality of aggregation variables and the quality parameter in a workpiece data set, a plurality of workpiece data sets being provided in accordance with steps a) to d) for a plurality of different workpieces; and
e) determining a respective interdependence between a respective aggregation variable and the quality parameter and identifying a forecasting variable from among the aggregation variables based on the determined interdependencies; and
f) specifying the forecasting variable for operation of the monitoring device as the quantity to be monitored of the production process;
wherein at least one of the aggregation variables is formed as a coefficient set of a fitting function, via which a variation with respect to time of at least one process variable is approximated in sections;
wherein a nonlinear interdependence is present between corresponding aggregation variables and the quality parameter; and
wherein an interdependence coefficient and the production process is a cyclical production process in which workpieces are repeatedly processed in the same way.

27. A production system comprising:
a plurality of components which are each configured to process a workpiece; and
a monitoring device connected to the components, wherein the monitoring device is configured as claimed in claim 26.
